(19) United States
(12) Patent Application Publication
(10) Pub. No.: US 2020/0287515 A1
(43) Pub. Date: Sep. 10, 2020

(54) COMPOSITE SUBSTRATE AND ACOUSTIC WAVE ELEMENT USING SAME

(71) Applicant: KYOCERA Corporation, Kyoto-shi, Kyoto (JP)

(72) Inventors: Motoki ITO, Ikoma-shi, Nara (JP); Tetsuya KISHINO, Nara-shi, Nara (JP); Soichiro NOZOE, Sohraku-gun, Kyoto (JP)

(21) Appl. No.: 16/758,159

(22) PCT Filed: Oct. 23, 2018
(86) PCT No.: PCT/JP2018/039380

§ 371 Date: Apr. 22, 2020

(30) Foreign Application Priority Data
Oct. 24, 2017 (JP) 2017-205212

(51) Int. Cl. H03H 9/02; H03H 9/145; H03H 9/25

(52) U.S. Cl. CPC H03H 9/02574; H03H 9/25; H03H 9/145; H03H 9/02559

(57) ABSTRACT

A composite substrate includes a first substrate which is comprised of a lithium tantalate crystal and has Euler angles (0, α, γ), and a second substrate which is comprised of a single crystal of silicon bonded to the first substrate and has Euler angles (−45, −54.7, β). In the composite substrate, α is −40° to −60° or 120° to 140° and γ is 0° or 180°, and either of following conditions is satisfied. (1) β is in a range of β=γ±20° and its equivalent orientation and (2) β is in a range of γ+160°≤β≤γ+200°.

### TECHNICAL FIELD

The present disclosure relates to a composite substrate and an acoustic wave element using the same.

### BACKGROUND ART

Conventionally, for the purpose of improving electrical characteristics, it is known to provide an electrode on a composite substrate formed by bonding a support substrate and a piezoelectric substrate to each other so as to fabricate an acoustic wave element. Here, the acoustic wave element is for example used as a bandpass filter in a mobile phone or another communication apparatus. Further, in Japanese Patent Publication No. 2006-319679A, there is known a composite substrate using lithium niobate or lithium tantalate (below, sometimes also referred to as “LT”) for forming the piezoelectric substrate and using silicon (Si) , quartz, ceramic, or the like for forming the support substrate.

### SUMMARY OF INVENTION

However, in recent years, the portable terminal devices used in mobile communications have been made increasingly smaller in size and lighter in weight and higher speech quality has been demanded. For this reason, an acoustic wave element provided with further higher electrical characteristics has been demanded. For example, in order to reduce leakage of an input and/or output signal to an adjacent channel, an acoustic wave element excellent in attenuation characteristic in a specific frequency band outside of the passing band has been demanded.

The present disclosure was made in consideration with such a subject and provides a composite substrate for providing an acoustic wave element excellent in electrical characteristics and provides an acoustic wave element using the same.

A composite substrate in the present disclosure includes a first substrate comprised of a lithium tantalate (LT) substrate and a second substrate comprised of a single crystal of silicon bonded to the first substrate. In the first substrate, the Euler angles are (0°, α, γ). In the second substrate, the Euler angles are (−45°, −54.7°, β). Further, a is −40° to −60° or 120° to 140°, γ is 0° or 180°, and either of the following conditions is satisfied: (1) β is in a range of β=γ±20° and its equivalent orientations and (2) β is in a range of γ+160°≤β≤γ+200°.

Another composite substrate in the present disclosure includes a first substrate comprised of a lithium tantalate (LT) substrate and a second substrate comprised of a single crystal of silicon bonded to the first substrate. In the first substrate, the Euler angles are (0°, α, γ). In the second substrate, the Euler angles are (−45°, −54.7°, β). Further, α is −40° to −60° or 120° to 140°, γ is 0° or 180°, and either of the following conditions is satisfied: (1) β is in a range of β=0°±20° and its equivalent orientations and (2) β is in a range of β=60°±20° and its equivalent orientations.

An acoustic wave element in the present disclosure includes the composite substrate explained above and an IDT electrode formed on an upper surface of the first substrate in the composite substrate.

According to the composite substrate described above, an acoustic wave element excellent in electrical characteristics can be provided.

### BRIEF DESCRIPTION OF DRAWINGS

FIG. 1A is a top surface view of a composite substrate according to the present disclosure, and FIG. 1B is a partially cutaway perspective view of FIG. 1A.

FIG. 2 is an explanatory diagram of a surface acoustic wave element according to the present disclosure.

FIG. 3A is a graph showing frequency characteristics of the acoustic wave element, and FIG. 3B is an enlarged view of a principal part in FIG. 3A.

FIG. 4A is a graph showing frequency characteristics of the acoustic wave element, and FIG. 4B is an enlarged view of a principal part in FIG. 4A.

FIG. 5A and FIG. 5B respectively show the results of computation showing the characteristics of the acoustic wave element when changing the Euler angles of a silicon crystal.

FIG. 6 is a view summarizing the relationships of combinations of the Euler angles of the first substrate and the second substrate and the characteristics of the acoustic wave element.

FIG. 7 is a graph showing the relationships between the strength of spurious emission and a direction of arrangement of a capacity part in an acoustic wave element according to a modification.

FIG. 8 is a graph showing the relationships between the strength of spurious emission and the Euler angles of the silicon crystal in the acoustic wave element according to the modification.

### DESCRIPTION OF EMBODIMENTS

Below, one example of a composite substrate and acoustic wave element in the present disclosure will be explained in detail by using the drawings.

(Composite Substrate)

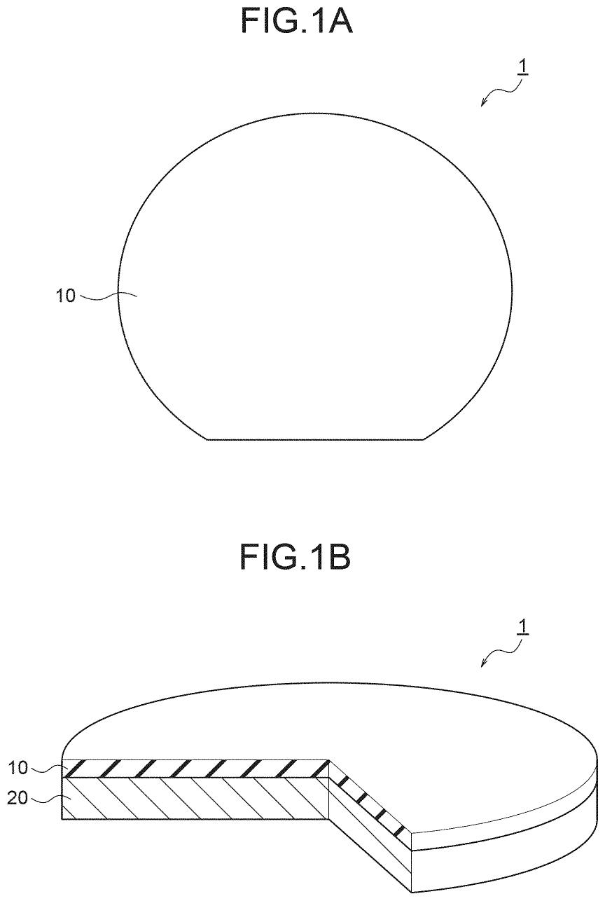

A composite substrate 1 in the present disclosure, as shown in FIGS. 1A and 1B, is so-called a bonded substrate and is configured by a first substrate 10 and a second substrate 20 bonded to the first substrate 10. Here, FIG. 1A is a top surface view of the composite substrate 1, and FIG. 1B is a perspective view of the composite substrate 1 in a partially cutaway state.

The first substrate 10 is configured by a substrate of single crystal having a piezoelectric characteristic comprised of an LT (LiTaO₃) crystal. Further, when the Euler angles (φ, θ, ψ) of the first substrate 10 are (0°, α, γ), “α” is equal to −40° to −60° or 120° to 140°. This becomes equivalent to either of a 30° to 50° Y-cut or a back surface of 30° to 50° Y-cut. Further, “γ” is made 0° or 180°.

The thickness of the first substrate 10 is constant and may be suitably set in accordance with the technical field to which the acoustic wave element is applied or the specifications demanded from the acoustic wave element and the like. Specifically, the thickness of the first substrate 10 may be set to 0.3 μm to 25 μm or may be made further thinner. The thickness may be made 1 to 20 times λ defined as 2 times a repetition interval (pitch) of electrode fingers 32 in an IDT electrode 31 explained later. In particular, when made 2λ or less, a loss of the acoustic wave can be lowered in the first substrate 10. Further, it may be made 0.1λ to 0.5λ as well. In this case, a resonance frequency of the acoustic wave excited by the IDT electrode 31 can be made higher. The planar shape and various dimensions of the first substrate 10 may be suitably set as well.

The second substrate 20 is comprised of a single crystal of Si. The single crystal of Si is provided with a strength strong enough to support the first substrate 10, therefore a composite substrate 1 having a high reliability can be provided. Further, the single crystal of Si is smaller in thermal expansion coefficient than the material for the first substrate 10. In this case, thermal stress is generated in the first substrate 10 when the temperature changes. At this time, a temperature dependency and stress dependency of the elastic constant are cancelled by each other, and in turn the change of the electrical characteristics of the acoustic wave element due to the temperature is compensated for.

The Euler angles (φ, θ, ψ) of the second substrate 20 are (−45°, −54.7°, β). The value of “β” will be explained later. The Euler angles explained above correspond to the (111) plane in the single crystal of Si.

The thickness of the second substrate 20 is for example constant and may be suitably set in the same way as the thickness of the first substrate 10. However, the thickness of the second substrate 20 is set by taking the thickness of the first substrate 10 into account so that the temperature compensation will be suitably carried out. As one example, the thickness of the second substrate 20 may be made thicker than the first substrate 10. While the thickness of the first substrate 10 is 1 to 30 μm, the thickness of the second substrate 20 is 50 to 300 μm. The planar shape and various dimensions of the second substrate 20 may be made equal to those of the first substrate 10 as well.

The first substrate 10 and the second substrate 20 may be bonded by so-called direct bonding activating the bonding surfaces by plasma, an ion gun, neutron gun, or the like, then bonding the bonding surfaces to each other without a bonding layer. In other words, the bonding surfaces of the first substrate 10 and the second substrate 20 are provided with flatness capable of direct bonding. In general, the arithmetic average roughness of the bonding surfaces enabling direct bonding is less than 1 nm. By bonding the substrates having such bonding surfaces to each other, the crystal planes of the two substrates contact each other, therefore an acoustic boundary becomes clear. Further, the bonding is not limited to direct bonding, and a not shown intermediate layer may be provided between the first substrate 10 and the second substrate 20 as well. By the intermediate layer, the bonding of the two is enabled, and acoustic characteristics can be adjusted. As the intermediate layer, SiO₂, Ta₂O₅, Si₃N₄, Si, AlN, and TiO₂ can be exemplified. These intermediate layers may be given for example a thickness not more than 1λ as well.

(Acoustic Wave Element)

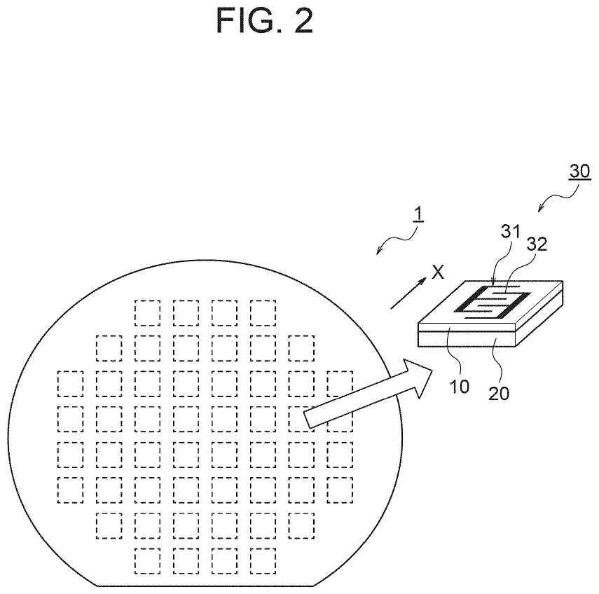

Further, the composite substrate 1 is divided into a plurality of sections as shown in FIG. 2. Each section becomes an acoustic wave element 30. Specifically, the composite substrate 1 is cut into pieces for each section to form the acoustic wave elements 30. In the acoustic wave element 30, an IDT electrode 31 exciting the surface acoustic wave is formed on the upper surface of the first substrate 10. The IDT electrode 31 has pluralities of electrode fingers 32, and the acoustic wave is propagated along the direction of arrangement of the pluralities of electrode fingers 32. Here, this direction of arrangement is substantially parallel to an X-axis of a piezoelectric crystal in the first substrate 10.

By using the composite substrate 1, the acoustic wave element 30 can suppress a change of frequency characteristics (electrical characteristics) due to a temperature change. On the other hand, the first substrate 10 is thin, and the second substrate 20 is bonded. Therefore, in the acoustic wave element 30, a bulk wave is reflected at the lower surface of the first substrate 10 and a bulk wave spurious emission is generated. If this bulk wave spurious emission is generated in a frequency band of the passing band of the other filter when configuring one filter by combining a plurality of IDT electrodes 31, there were possibilities that an isolation characteristic would be degraded and a loss in that frequency band would become large. In particular, provision of a resonator having a small loss on a higher frequency side than the antiresonance frequency has been demanded.

As a result of intensive studies by the present inventors for such a bulk wave spurious emission on a higher frequency side than the antiresonance frequency, they found that a reduction of the loss at a higher frequency than the antiresonance frequency could be realized and an attenuation characteristic could be raised by making the relationships of the propagation angle of the second substrate 20 relative to the propagation angle of the first substrate 10 certain relationships. Note that, the “adjusting propagation angles” between the first substrate 10 and the second substrate 20 means changing ψ in the Euler angles (φ, θ, ψ) to cause rotation and adjusting the relationship between “β” and “γ”. This also means rotation of the second substrate 20 relative to the first substrate 10 and also means change of the direction of the silicon crystal relative to the X-axis of the piezoelectric crystal in the first substrate 10. For this reason, below, sometimes “adjust the propagation angles” will be indicated based on the “ψ” in the Euler angles (“γ” in the first substrate 10 and “β” in the second substrate 20) or will be shown by the angle formed by the silicon crystal relative to the X-axis of the first substrate 10.

(Embodiment of Composite Substrate 1)

Below, an example of the configuration of the composite substrate 1 capable of reducing the loss on a higher frequency side than the antiresonance frequency will be explained. First, as the second substrate 20, use is made of one making the plane orientation of silicon (111) and making the orientation of the orientation flat an orientation obtained by rotation from the usual {110} by an angle of 0°±20° or 60°±20°. Note that, {110} indicates the orientation and does not generally show planes equivalent to the (110) plane.

Here, for example, rotation by 60° gives a crystal orientation of the second substrate 20, expressed in terms of Euler angles, (−45°, −54.7°, 60°). That is, β is made equal to 60°. Further, the orientation flat of the first substrate 10 is provided so as to be perpendicular to the direction of propagation of the acoustic wave, therefore the second substrate 20 is bonded so that the normal line of the orientation {110} of the crystal of the silicon is inclined by 60° relative to the direction of propagation of the acoustic wave, that is, the X-axis of the piezoelectric crystal. Note that, the orientation flat of the first substrate 10 is perpendicular to the direction of propagation of the acoustic wave (X-axis direction of the LT substrate) . In other words, this is the same in meaning as that “β” of the second substrate 20 becomes the angle of the [1-10] direction of Si relative to the direction of propagation (X-axis) of the first substrate 10.

In other words, when “γ” of the first substrate 10 is made 0° or 180°, “β” of the second substrate 20 is set to 0°±20° or 60°±20°.

When the acoustic wave element 30 is configured by using such a composite substrate 1, the loss on a higher frequency side than the antiresonance frequency can be reduced. Below, the effect thereof will be verified.

A simulation was run for a model of an acoustic wave element 30 having an IDT electrode 31 formed on the composite substrate 1 of the present disclosure. The model of the fundamental configuration of the acoustic wave element 30 is as follows:

[First Substrate 10]

Material: 42° Y-cut, and X-propagated LT substrate

Euler angles: (0°, −48°, γ)

Thickness: 2.2 μm

[IDT Electrode 31]

Material: Al—Cu alloy

(however, there is an underlying layer of 6 nm made of Ti between this and the first substrate 10)

Thickness (Al—Cu alloy layer): 420 nm

Electrode fingers 32 in IDT electrode 31:
(Number) Arranged in infinite cycle
(Pitch) 2.7 μm
(Duty) 0.5
(Intersecting width) 20λ (λ=2×pitch)

[Protective Layer Covering IDT Electrode 31]

Material: SiO₂

Thickness: 15 nm

[Second Substrate 20]

Material: Single crystal of silicon

Thickness: 230 μm

Crystal orientation: (111)

As the acoustic wave element 30 in the present embodiment, models changing the propagation angles of the first substrate 10 and the second substrate 20 were prepared, and simulation was carried out. Specifically, this is as follows.

Example 1: “γ” of the first substrate 10 is made equal to 0°, and “β” in Euler angles (φ, θ, ψ)=(−45, −54.7, β) of the second substrate 20 is changed.

Example 1-1: β=0°

Example 1-2: β=20°

Example 1-3: β=40°

Example 1-4: β=60°

Example 2: “γ” of the first substrate 10 is made equal to 180°, and “β” in Euler angles (φ, θ, ψ)=(−45, −54.7, β) of the second substrate 20 is changed.

Example 2-1: β=0°

Example 2-2: β=20°

Example 2-3: β=40°

Example 2-4: β=60°

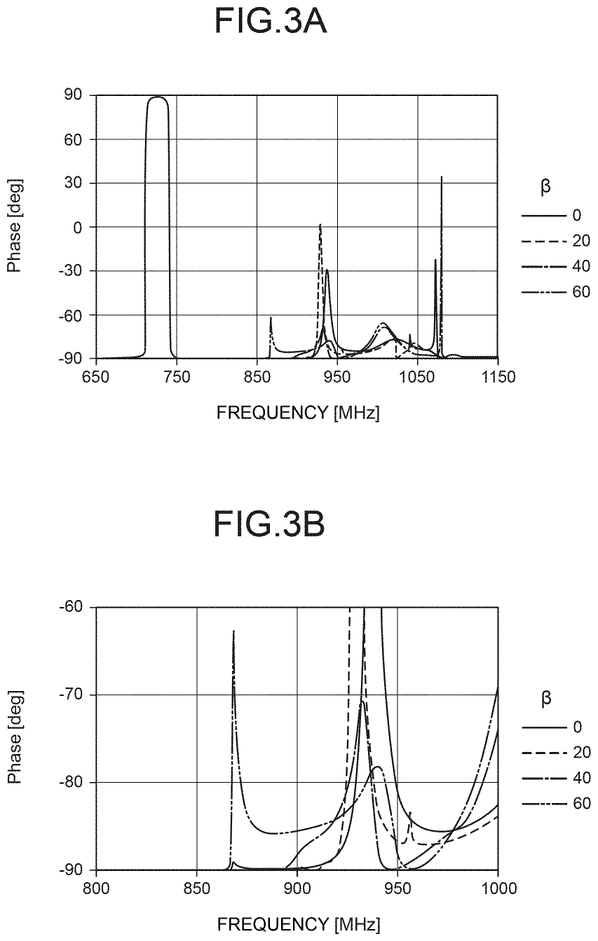

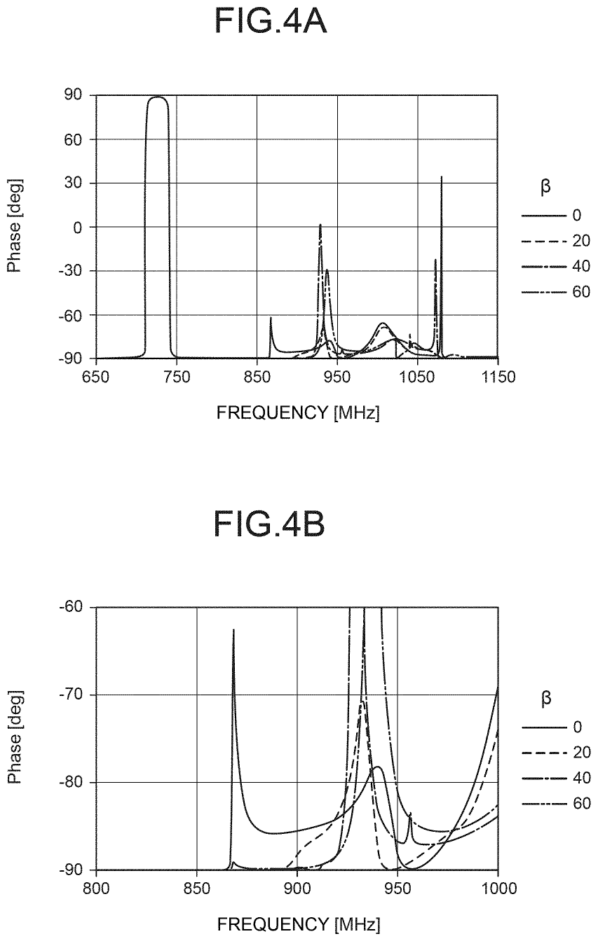

The phase characteristics of Examples 1 and 2 will be shown in FIGS. 3A and 3B and FIGS. 4A and 4B. In FIGS. 3A and 3B and FIGS. 4A and 4B, the ordinates show the phases (unit: deg), and the abscissas show the frequencies (unit: MHz) . FIG. 3A and FIG. 4A are graphs showing the characteristics in a broad frequency range including the resonance frequencies and antiresonance frequencies, and FIG. 3B and FIG. 4B are enlarged graphs of parts in FIG. 3A and FIG. 4A and show the characteristics at the higher frequency sides than the antiresonance frequencies.

As apparent from FIG. 3B, it is seen that, in the case of γ=0°, if β is made equal to 0°±20°, the buildup of spurious emission becomes small, and start of the buildup can be shifted to the high frequency side. Note that, the buildup of the spurious emission is judged to start from a frequency where the phase becomes larger than −85° on a higher frequency side than the antiresonance frequency.

In the same way, as apparent from FIG. 4B, in the case of γ=180°, the same tendency can be confirmed at the time of β=60°±20°.

Here, the (111) crystal of silicon has rotation symmetry of 120°, therefore β=60° and β=180° are equal. From this, β=0° at the time of γ=0° and β=60° at the time of γ=180° become the same in the meaning as making “γ” and “β” substantially coincide. It was seen from this that, by making “γ” and “β” substantially coincide, the buildup of the spurious emission became small and the start of buildup could be shifted to the high frequency side. Making “γ” and “β” substantially coincide, in other words, means making β=γ±20° in range or adjustment to give an orientation equivalent to this.

Next, as apparent from FIG. 3A, it is seen that in the case of γ=0°, if making β=60±20°, the strength of the spurious emission can be made smaller. In the same way, as apparent from FIG. 4A, it is seen that in the case of γ=180°, if satisfying β=0°±20°, the strength of the spurious emission can be made smaller.

Here, the (111) crystal of silicon has rotation symmetry of 120°, therefore β=60° and β=180° are equal. From this, β=60° at the time of γ=0° and β=0° at the time of γ=180° become the same in the meaning as making “γ” and “β” offset by 180°, that is, making them substantially match with γ=180°+β. It was seen from this that, by making the relationships substantially match with γ=180°+β, the absolute strength of spurious emission could be made smaller. Making the relationships substantially match with γ=180°+β, in other words, means making the orientation fall in a range of γ+160°≤β≤γ+200° or adjusting the orientation so as to become equivalent to this.

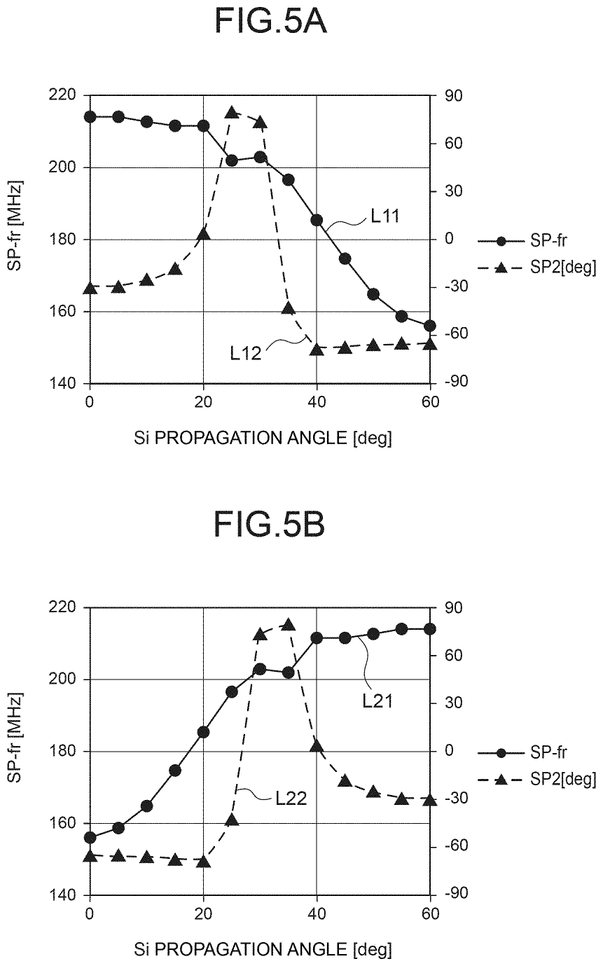

Here, further, an interval (Sp-fr) from the resonance frequency up to the point of buildup of spurious emission and the maximum phase (SP2) of the spurious emission when “β” was finely changed were respectively found and were shown in FIGS. 5A and 5B. FIG. 5A shows the results at the time of γ=0°, and FIG. 5B shows the results at the time of γ=180°.

In FIG. 5A, the trend in “Sp-fr” is indicated by a line L11, and the trend in Sp2 is indicated by a line L12. In the same way, in FIG. 5B, the trend in “Sp-fr” is indicated by a line L21, and the trend in Sp2 is indicated by a line L22.

As apparent also from FIGS. 5A and 5B, in a region where “β” exceeds 20° and is less than 40°, “Sp-fr” becomes smaller and Sp2 takes the maximum value . From the above explanation, by bonding the first substrate 10 and the second substrate 20 to each other while adjusting the relationships of “γ” and “β” so that “β” does not become equal to 21° to 39°, an acoustic wave element excellent in the attenuation characteristic can be realized.

Further, it is confirmed that “Sp-fr” is stably large in regions from 0° to 20° on L11 and from 40° to 60° on L21 (that is, regions where β≈γ stands). Further, it was confirmed that Sp became small as well at 0° on L11 and at 60° on L21 where “β” became equal to “γ”. From this fact, in a case where “β” is made equal to γ±5°, “Sp-fr” is large, and Sp2 can be made small.

In the same way, it is confirmed that Sp2 is stably small in regions from 40° to 60° on L12 and from 0° to 20° on L22 (that is, regions where γ≈180°+β stands). Further, in any case, it was confirmed that Sp became the smallest and “Sp-fr” became large as well at 40° on L12 and at 20° on L22 which were offset by about 20° to 15° from γ=180°+β.

From the above explanation, in the case of γ≈β and Euler angles equivalent to this at the time when the Euler angles of the first substrate 10 are set to (0°, −40° to −60°, γ), the Euler angles of the second substrate 20 are set to (−45°, −54.7, β), and “γ” is made 0° or 180°, “Sp-fr” can be stably made large. That is, the spurious emission is shifted to a high frequency side, and the strength of the entire spurious emission can be lowered. Further, in the case of γ≈180°+β and Euler angles equivalent to that, the strength of Sp2 can be made small. That is, it was confirmed that the strength of spurious emission could be made small.

Note that, here, on the Si (111) plane, “β” at which the values are equivalent to 0° are 120° and 240°, and “β” at which the values are equivalent to 60° are 180° and 300°. That is, as the angles which are equivalent to the Euler angles (−45, −54.7, −20 to 20) of the second substrate 20, there can be mentioned (−45, −54.7, 100 to 140) and (−45, −54.7, 220 to 260). In the same way, as the angles equivalent to (−45, −54.7, 40 to 80), there can be mentioned (−45, −54.7, 160 to 200) and (−45, −54.7, 280 to 320).

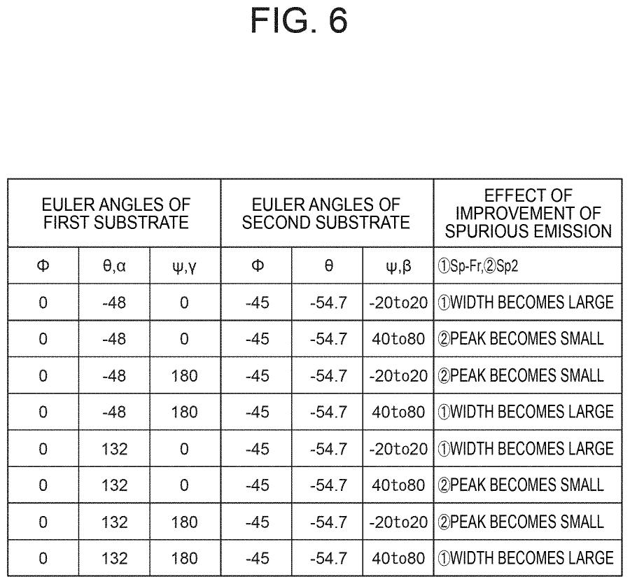

In the example explained above, the case where the Euler angles of the first substrate 10 were set to (0°, −40° to −60°, γ) was explained. The same is true for the case of (0°, 120° to 140°, γ). The results by checking the magnitude of “Sp-fr” and the magnitude of Sp2 when the Euler angles were respectively combined will be shown in FIG. 6. As apparent also from FIG. 6, it was confirmed that manifestation of the effect explained above could be controlled by adjusting the relationships between “γ” and “β” even if there was a difference in “α”.

Note that, it is confirmed that the characteristics explained above are manifested so far as the angle of “φ” in the Euler angles of the first substrate 10 and the angles of “φ” and “θ” in the Euler angles of the second substrate 20 are within the range of ±5° about the exemplified numerical values.

Further, it is confirmed that the magnitude of “Sp-fr” becomes small when “γ” is offset from 0° and 180°.

Further, it is also possible to extract the following concept from the disclosure explained above.

That is, this Description discloses an LT/Si bonded wafer formed by bonding LT in which the Euler angles are set to (0, α, γ) where “α” is −40° to −60° (corresponding to 30° to 50° Y-cut) or 120° to 140° (30° to 50° Y-cut back surface) , and “γ” is 0° or 180°, and the Si in which the Euler angles are (−45, −54.7, β) to each other, wherein:

(1) “β” is in a range of 0°±20° and its equivalent orientations or (2) “β” is in a range of 60°±20° and its equivalent orientations. In the case of (1), a spurious emission which is generated at a high frequency of the bandwidth can be shifted to a higher frequency or can be reduced. In the case of (2), the peak of the spurious emission generated at a high frequency can be made smaller.

Note that, an intermediate layer may be positioned at an interface of the LT and the Si as well.

<Modification>

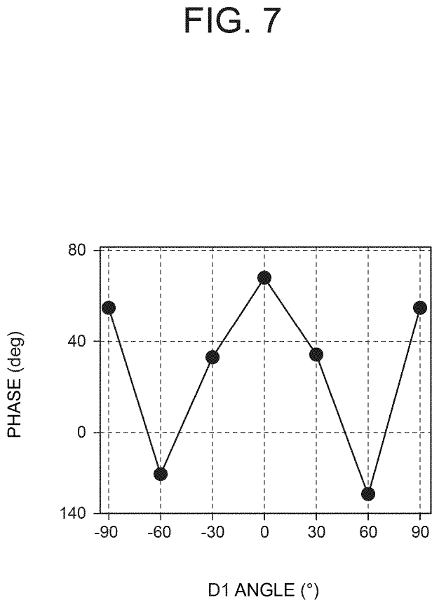

The acoustic wave element 30 may be provided with a capacity part 60 which is connected in parallel to the IDT electrode 31 as well. By the capacity part 60, the difference (df) between the resonance frequency and the antiresonance frequency can be made small, therefore adjustment can be carried out so that the desired df is provided. In a case where such a capacity part 60 is formed by an interdigital type electrode the same as the IDT electrode 31, the direction D1 of repeated arrangement of the electrode fingers 43 in the capacity part (capacity part electrode fingers 43) may be made different from the direction of arrangement of the electrode fingers 32 in the IDT electrode 31 functioning as the resonator. By employing such a configuration, the influence of resonation by the capacity part 60 can be reduced. Further, as shown in FIG. 7, where the direction D1 of arrangement is set to −60°±5° or 60°±5°, the maximum strength of the spurious emission which is positioned on a higher frequency side than the resonance frequency (fr) can be made low. Note that, γ=0° or 180°, therefore the direction D1 of arrangement ends up becoming −60°±5° or 60°±5° relative to the X-axis.

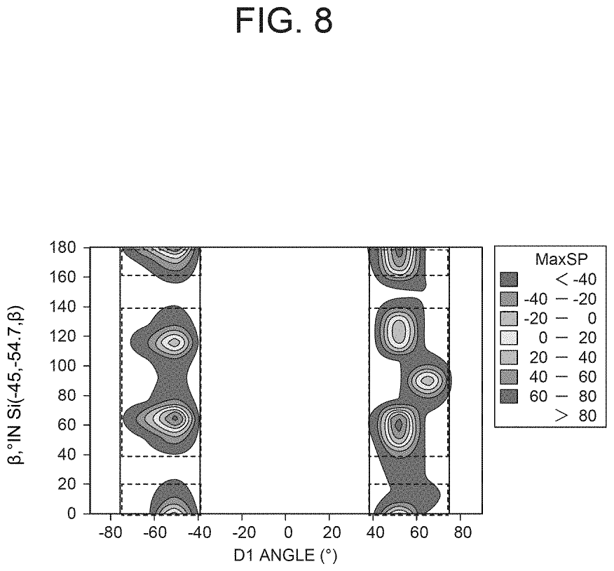

Here, the maximum strength of the spurious emission when changing “β” in the second substrate 20 was simulated for the acoustic wave element 30 including the capacity part 60. The result will be shown in FIG. 8. In FIG. 8, the abscissa shows the direction D1 of arrangement, the ordinate shows “β”, and the maximum strength (MaxSP) of the spurious emission is indicated by a contour line. As apparent also from FIG. 8, in the case where “β” in the second substrate 20 is set to 0° to 20°, 40° to 140°, or 160° to 180°, the strength of the spurious emission can be made small. That is, in the case where “β” in the second substrate 20 is set to 0° to 20°, 40° to 80°, or 160° to 180°, as explained before, in addition to reduction of the loss on a higher frequency side than the antiresonance frequency due to the IDT electrode 31, the loss on a higher frequency side than the antiresonance frequency due to the capacity part 60 can also be reduced.

Note that, it is confirmed that the relationships of the direction D1 of arrangement in such a capacity part 60 and the Euler angles of the second substrate 20 are the same between the case where there is an intermediate layer between the first substrate 10 and the second substrate 20 and the case where there is no intermediate layer.

### REFERENCE SIGNS LIST

1: composite substrate

10: first substrate

20: second substrate

30: acoustic wave element

31: IDT electrode

1. A composite substrate, comprising:
a first substrate which is comprised of a lithium tantalate crystal and has Euler angles (0, α, γ) and
a second substrate which is comprised of a single crystal of silicon bonded to the first substrate and has Euler angles (−45, −54.7, β), wherein
α is −40° to −60° or 120° to 140° and γ is 0° or 180°, and
the composite substrate satisfies either of following conditions:
(1) β is in a range of β=γ±20° and its equivalent orientations and
(2) β is in a range of γ+160°≤γ≤γ+200° and its equivalent orientations.

2. A composite substrate, comprising:
a first substrate which is comprised of a lithium tantalate crystal and has Euler angles (0, α, γ) and
a second substrate which is comprised of a single crystal of silicon bonded to the first substrate and has Euler angles (−45, −54.7, β), wherein
α is −40° to −60° or 120° to 140° and γ is 0° or 180°, and the composite substrate satisfies either of following conditions:
(1) β is in a range of β=0°±20° and its equivalent orientations, and
(2) β is in a range of β=60°±20° and its equivalent orientations.

3. The composite substrate according to claim 1, wherein the first substrate is thinner compared with the second substrate.

4. The composite substrate according to claim 1, wherein a crystal plane of the lithium tantalate crystal and a crystal plane of the single crystal of silicon directly contact at bonding surfaces of the first substrate and the second substrate.

5. The composite substrate according to claim 1 wherein one or more intermediate layers are located between the first substrate and the second substrate.

6. An acoustic wave element, comprising:
the composite substrate according to claim 1 and
an IDT electrode on an upper surface of the first substrate in the composite substrate.

7. The acoustic wave element according to claim 6, wherein
the IDT electrode comprises a plurality of electrode fingers, and
a thickness of the first substrate is 2λ or less, where λ is two times of an interval of the electrode fingers.

8. The acoustic wave element according to claim 1, comprising an interdigital type capacity part which is connected in parallel to the IDT electrode and comprises a plurality of capacity part electrode fingers, wherein
a direction of arrangement of the capacity part electrode fingers forms an angle of 60°±5° or −60°±5° relative to a direction of arrangement of the electrode fingers in the IDT electrode.

9. The acoustic wave element according to claim 8, wherein “β” in the second substrate is any of 0° to 20°, 40° to 140°, and 160° to 180°.

10. An acoustic wave element, comprising:
the composite substrate according to claim 2 and
an IDT electrode on an upper surface of the first substrate in the composite substrate; wherein
the IDT electrode comprises a plurality of electrode fingers, and
a thickness of the first substrate is 2λ or less, where λ is two times of an interval of the electrode fingers.
